(19) United States
(12) Patent Application Publication
(10) Pub. No.: US 2002/0047749 A1
(43) Pub. Date: Apr. 25, 2002

(54) Chip element mounting method and surface-mount type crystal oscillator

(75) Inventor: Kenichi Sugawara, Saitama (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Nihon Dempa Kogyo Co., Ltd., Tokyo (JP)

(21) Appl. No.: 09/983,238

(22) Filed: Oct. 23, 2001

(30) Foreign Application Priority Data
Oct. 24, 2000 (JP) 2000-323702

(51) Int. Cl. H03B 5/32

(52) U.S. Cl. 331/158

(57) ABSTRACT

A method is provided for mounting microchip elements such as capacitors on a substrate or printed board, the method enabling both the prevention of electrical short-circuits and an improvement in shock resistance. In a mounting method in which a chip element having mounting electrodes is secured to a substrate by a conductive adhesive, a substrate is used in which depressions are formed in correspondence with securing points, the depressions are filled with conductive adhesive while controlling the amount, the mounting electrodes and the conductive adhesive are brought into contact, and the conductive adhesive is then cured. This mounting method is preferably used to secure a capacitor to the bottom surface of a vessel in a surface-mount type crystal oscillator that has a construction in which a crystal blank, an IC chip, and a capacitor as the chip element are accommodated in the vessel.

### BACKGROUND OF THE INVENTION

1. Field of the Invention

The present invention relates to a method of mounting a chip element, and more particularly to a method of mounting a chip element such as a micro-capacitor, and to a crystal oscillator in which a chip element is mounted by this method.

2. Description of the Related Art

Crystal oscillators that are surface-mounted on, for example, printed boards are widely used as frequency and time reference sources in various electronic devices including communication equipment, and in particular, portable devices. With the increased miniaturization of portable devices in recent years, there is increasing demand for still smaller and lighter surface-mount type crystal oscillators.

FIG. 1 is a sectional view showing the construction of a surface-mount type crystal oscillator of the prior art. This oscillator has surface-mount type vessel or receptacle 1 made of multilayered ceramics and accommodates IC (Integrated Circuit) chip 2, capacitors 3, and crystal blank 4 within vessel 1. Vessel 1 has a cavity in which the upper end is an open end, this opening being sealed by cover 5. Stepped portions are formed on the inner walls of vessel 1, i.e., the inner walls of the cavity.

IC chip 2 is a component that integrates the various elements such as amplifiers that, together with crystal blank 4, constitute the oscillator circuit, and is secured to the inner bottom surface of vessel 1 by facedown bonding such as ultrasonic welding using bumps (not shown in the figure). As shown in FIG. 2, crystal blank 4 has excitation electrodes 6a and 6b on its two major surfaces, and is provided with extended electrode 7a that extends from excitation electrode 6a toward one end of crystal blank 4 and another extended electrode 7b that extends from excitation electrode 6b toward the other end of crystal blank 4. Crystal blank 4 is secured to the stepped portion of the inner wall of vessel 1 by a conductive adhesive at the positions of extended electrodes 7a and 7b.

Capacitors 3 are formed as chip elements and have a high capacitance that more than offsets the difficulty involved in integrating them within IC chip 2. Capacitors 3 are, for example, bypassing capacitors or RF (radio-frequency) coupling capacitors. Capacitors 3 are approximately rectangular shapes with a mounting electrode 8a and 8b formed at each end, respectively. Conductive adhesive 9 is applied by means of a dispenser at prescribed points of the inner bottom surface of vessel 1 as shown in FIG. 3, capacitors 3 are mounted such that mounting electrodes 8a and 8b are floating in this conductive adhesive 9, and capacitors 3 are secured to the bottom surface of vessel 1 by the curing of conductive adhesive 9.

Although not shown in the figures, a circuit pattern is formed on the surface of the cavity of vessel 1 to interconnect IC chip 2, capacitors 3, and crystal blank 4. In addition, outer electrodes (not shown in the figure) are provided on the outer walls of vessel 1 to connect this surface-mount type oscillator to outside circuits, and these outer electrodes are electrically connected to the circuit pattern.

In the surface-mount type oscillator according to the foregoing description, the size of capacitors 3 has decreased as miniaturization has accelerated, and the amount of conductive adhesive 9 that is required for securing capacitors 3 has also decreased. However, controlling the amount of conductive adhesive 9 that is applied by a dispenser is extremely problematic when the amount of conductive adhesive is very small. An excessive amount of conductive adhesive 9 results in the problem that surplus conductive adhesive 9 causes electrical short-circuits with the adjacent printed pattern. An insufficient amount, on the other hand, decreases the strength of the connection with capacitors 3, resulting in the problem that shocks to the unit may cause conductive adhesive 9 or capacitors 3 to be dislodged from the bottom surface of vessel 1.

### SUMMARY OF THE INVENTION

It is an object of the present invention to provide a method of mounting chip elements, such as capacitors, resistors, thermistors and diodes, that can both prevent electrical short-circuits and improve shock resistance.

It is another object of the present invention to provide a surface-mount type crystal oscillator that employs the method of mounting chip elements that can both prevent electrical short-circuits and improve shock resistance.

The object of the present invention can be realized by a mounting method in which a chip element having a mounting electrode is secured to a substrate or printed board, this mounting method including the steps of: using a substrate, in which a depression is formed corresponding to securing position; filling the depression with a conductive adhesive while controlling the amount; and fixing the chip element to the substrate by the conductive adhesive.

Another object of the present invention can be realized by a crystal oscillator for surface mounting which has a construction in which a crystal blank, an IC chip and a capacitor are accommodated in a vessel, the capacitor being a chip element; the crystal oscillator comprising a conductive adhesive that is applied to a depression provided in a bottom surface of the vessel; wherein the capacitor is secured to the bottom surface of the vessel by the conductive adhesive.

### BRIEF DESCRIPTION OF THE DRAWINGS

FIG. 1 is a sectional view showing a surface-mount type oscillator of the prior art;

FIG. 2 is a plan view of a crystal blank;

FIG. 3 is a partial sectional view of the surface-mount type oscillator of the prior art;

FIG. 4 is a partial sectional view of a surface-mount type oscillator according to a preferable embodiment of the present invention; and

FIG. 5 is a partial plan view of the surface-mount type oscillator shown in FIG. 4.

### DETAILED DESCRIPTION OF THE PREFERRED EMBODIMENTS

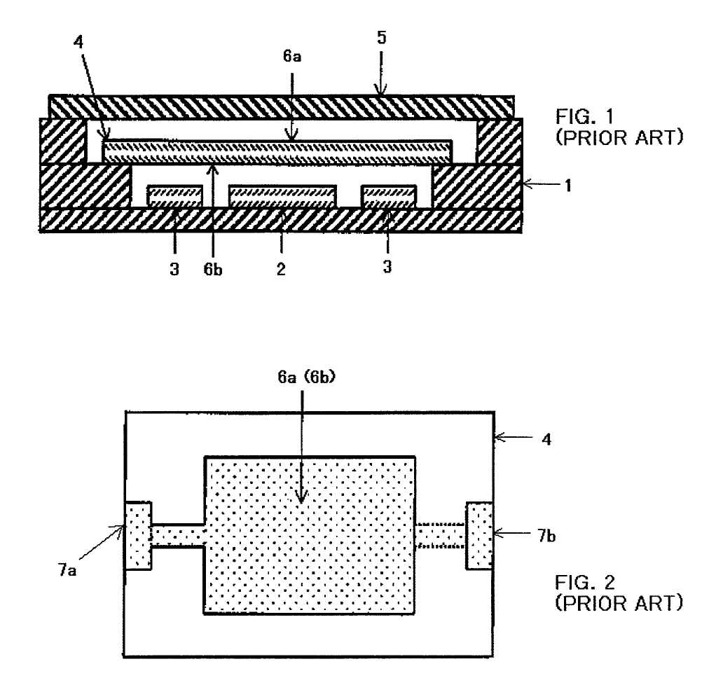

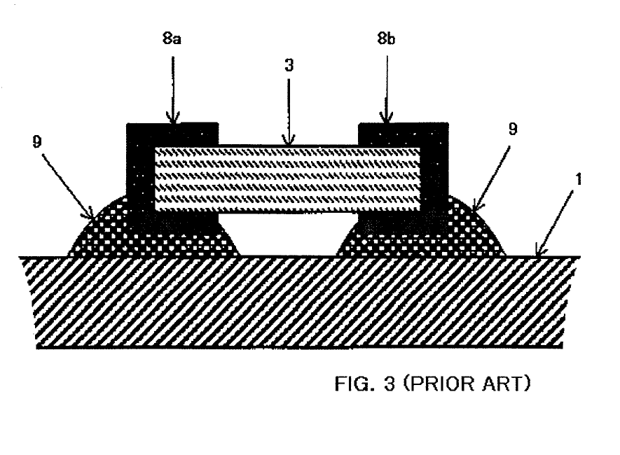

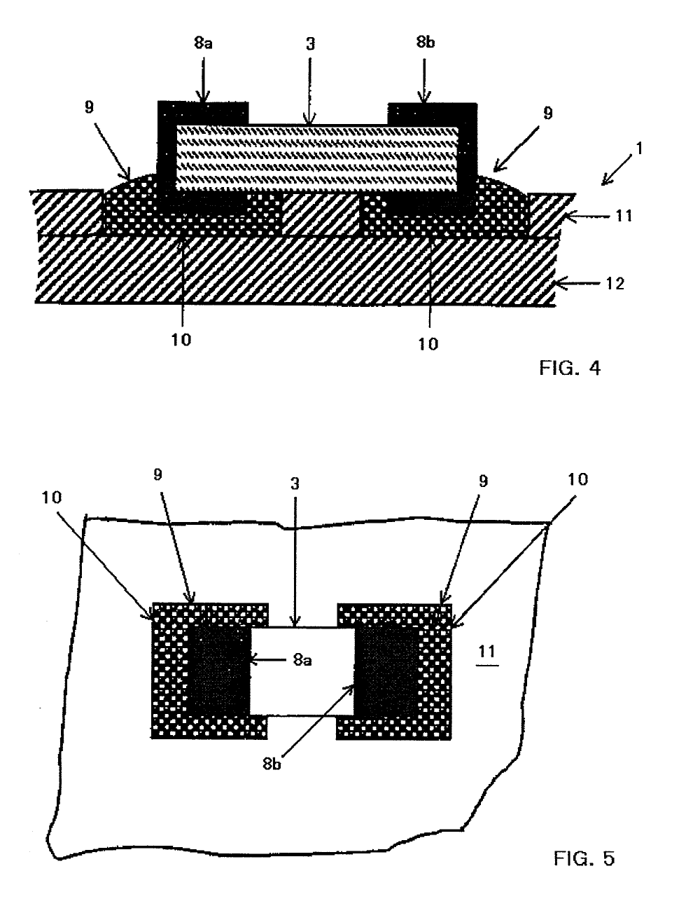

Referring now to FIGS. 4 and 5, the surface-mount type crystal oscillator according to a preferable embodiment of the present invention is equivalent to the oscillator shown in FIGS. 1 to 3 with the exception of the differences of the construction for securing capacitor 3 to the inner bottom surface of vessel 1. In the following explanation, those constituent elements having the same reference numerals as elements in FIGS. 1 to 3 are the same as the constituent elements in FIGS. 1 to 3.

As with the previously described oscillator shown in FIGS. 1 to 3, the surface-mount type crystal oscillator of this embodiment includes vessel 1 having a cavity in which stepped portions are formed, IC chip 2, capacitors 3, and crystal blank 4. IC chip 2, capacitors 3 and crystal blank 4 are sealed in vessel 1. Crystal blank 4 is held in vessel 1 by securing both ends of crystal blank 4 to the stepped portions of the inner walls of vessel 1 by conductive adhesive. IC chip 2 is secured to the bottom surface of vessel 1 by, for example, ultrasonic welding, and capacitors 3 are secured to the bottom surface of vessel 1 by conductive adhesive 9.

In this oscillator, depressions 10 are formed in the inner bottom surface of vessel 1 in correspondence with the two ends of each secured capacitor 3. These depressions 10 are formed by, for example, laminating plate 11 composed of ceramic in which through-holes have been formed in correspondence with depressions 10 on a flat plate 12 composed of ceramic as the bottom surface of vessel 1. Electrode terminals or a metalized layer that connects with the circuit pattern is provided in advance on the inside bottom surfaces and inner circumferences of depressions 10.

Explanation next regards the method of mounting capacitor 3.

Assuming depressions 10 as described in the foregoing explanation are formed in the bottom surface of vessel 1, conductive adhesive 9 is first applied to fill the inside of depressions 10 by a dispenser not shown in the figure. Capacitor 3 having a mounting electrode 8a and 8b formed at each end is next placed on conductive adhesive 9 such that each of mounting electrodes 8a and 8b contacts conductive adhesive 9 in a respective depression 10. Capacitor 3 is then secured onto the bottom surface of vessel 1 by curing by means of thermosetting conductive adhesive 9. At this time, the lower surfaces of mounting electrodes 8a and 8b that are shown in the figure are positioned inside depressions 10, i.e., at a lower level than the upper surface of plate 11, by controlling the amount of conductive adhesive 9 that is applied, mounting electrodes 8a and 8b being embedded in conductive adhesive 9.

In this type of mounting method, the provision of depressions 10 allows control of the proper amount of conductive adhesive 9, and depressions 10 can be filled with an appropriate amount of conductive adhesive 9. This method therefore can not only prevent electrical short-circuits with the circuit pattern caused by surplus amounts of conductive adhesive 9, but can maintain appropriate connective strength and improve shock resistance.

The method of forming depressions 10 in the present invention is not limited to the above-described method of laminating ceramics. For example, the depressions may be formed by a metal mold when forming ceramic vessel 1, or the depressions may formed by printing after forming vessel 1.

The shape of vessel 1 is not limited to a form having a cavity with an opening formed in one end, but may also be a form having an H-shaped section with cavities in the two opposite surfaces. The vessel may also be formed such that the component-mounting surface is a plate over which a cover having a cavity is placed.

The chip elements are not limited to capacitors. The present invention can be applied to mounting various chip elements including, for example, resistors, thermistors and diodes.

The mounting method of the present invention is particularly suited to surface-mount type crystal oscillators, but if the bottom surface of the vessel in the foregoing explanation is considered as a substrate or a printed board, the mounting method of the present invention may be used as a common method for securing and mounting chip elements to ordinary printed boards or substrates.

What is claimed is:

1. A mounting method in which a chip element having a mounting electrode is secured to a substrate, said mounting method comprising the steps of:
using a substrate, in which a depression is formed corresponding to securing position;
filling said depression with a conductive adhesive while controlling amount; and
fixing said chip element to said substrate by said conductive adhesive.

2. A mounting method according to claim 1, said fixing steps including the steps of bringing said mounting electrode and said conductive adhesive into contact, and then curing said adhesive.

3. A mounting method according to claim 1, wherein an electrode that connects to a circuit pattern is formed in advance in said depression.

4. A mounting method according to claim 1, wherein said chip element has said mounting electrode at each of both ends thereof, and wherein each of both mounting electrodes is secured to said substrate by said conductive adhesive.

5. A mounting method according to claim 3, wherein said chip element has said mounting electrode at each of both ends thereof, and said depression is formed in said substrate at a position corresponding to each of said ends.

6. A mounting method according to claim 4, wherein said chip element is a capacitor.

7. A mounting method according to claim 5, wherein said chip element is a capacitor.

8. A crystal oscillator for surface mounting which has a construction in which a crystal blank, an IC (integrated circuit) chip and a capacitor are accommodated in a vessel, said capacitor being a chip element; said crystal oscillator comprising:
a conductive adhesive that is applied to a depression provided in a bottom surface of said vessel;
wherein said capacitor is secured to the bottom surface of said vessel by said conductive adhesive.

9. A crystal oscillator according to claim 8, wherein said capacitor has mounting electrodes at both ends thereof, and said depression is formed in said substrate at a position corresponding to each of said ends.

10. A crystal oscillator according to claim 8, wherein said crystal blank is secured to a stepped portion of an inner wall of said vessel by a conductive adhesive.
